(19) United States
(12) Patent Application Publication
(10) Pub. No.: US 2026/0114110 A1
(43) Pub. Date: Apr. 23, 2026

(54) CHEMICAL COMPOSITION, OPTOELECTRONIC COMPONENT COMPRISING AT LEAST ONE CHEMICAL COMPOSITION OF THIS TYPE, AND USE OF AT LEAST ONE CHEMICAL COMPOSITION OF THIS TYPE IN AN OPTOELECTRONIC COMPONENT

(71) Applicant: Heliatek GmbH, Dresden (DE)

(72) Inventors: Ludovic COUTABLE; Roland FITZNER; Gunter MATTERSTEIG

(21) Appl. No.: 19/116,991

(22) PCT Filed: Sep. 28, 2023
(86) PCT No.: PCT/DE2023/100727

§ 371 Date: Mar. 28, 2025

(30) Foreign Application Priority Data
Sep. 30, 2022 (DE) 10 2022 125 417.8

(51) Int. Cl. H10K 50/11; C07F 5/02; C07F 7/08; C07F 9/6596; H10K 85/40; H10K 85/60

(52) U.S. Cl. CPC H10K 50/11; C07F 5/022; C07F 7/0816; C07F 9/6596; H10K 85/40; H10K 85/658

(57) ABSTRACT

A chemical compound of the general formula Ia or Ib may be or include

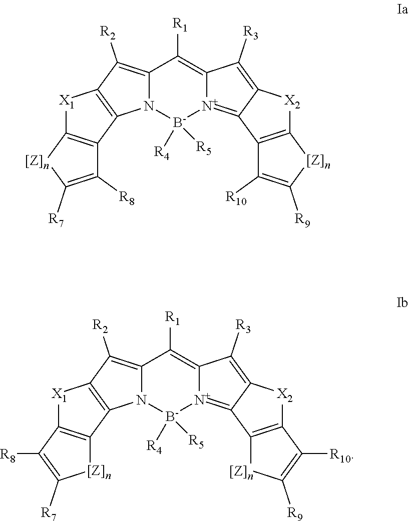

An optoelectronic component may include a layer system having the above-mentioned compound too.

### CROSS REFERENCE TO RELATED APPLICATIONS

The present application is a national stage entry according to 35 U.S.C. § 371 of PCT application No.: PCT/DE2023/100727 filed on Sep. 28, 2023; which claims priority to German Patent Application Serial No.: 10 2022 125 417.8, which was filed on Sep. 30, 2022; which are incorporated herein by reference in their entirety and for all purposes.

### TECHNICAL FIELD

The present invention relates to a chemical compound, to an optoelectronic component comprising at least one chemical compound of this type, and to a use of at least one chemical compound of this type in an optoelectronic component.

### BACKGROUND

Organic optoelectronic components have a photoactive layer in which incident electromagnetic radiation results in generation of charge carriers, in particular bound electron-hole pairs (excitons). By diffusion, the excitons arrive at an interface at which electrons and holes are separated from one another. The material that accepts the electrons is referred to as acceptor, and the material that accepts the holes is referred to as donor. Organic optoelectronic components permit the conversion of electromagnetic radiation into electric current through utilization of the photoelectric effect. A conversion of electromagnetic radiation of this kind requires absorber materials that show good absorption properties.

Organic optoelectronic components are known from the prior art. WO 2004/083958 A2 discloses a photoactive component, in particular a solar cell, consisting of organic layers of one or more pi, ni, and/or pin diodes stacked on top of one another. WO 2011/161108 A1 discloses a structure of an organic solar cell consisting of a pin or nip diode. A pin solar cell consists of a substrate having an electrode disposed thereon, p layer(s), i layer(s), n layer(s), and a counterelectrode. In this context, n and p respectively mean n and p doping, which results in an increase in the density of free electrons/holes in a state of thermal equilibrium. The term “i layer” refers to an undoped layer (intrinsic layer) with an absorber material or a mixture of two or more absorber materials. One or more i-layers may here consist of one material (planar heterojunctions) or else of a mixture of two or more materials (bulk heterojunctions). An absorber material, i.e. an absorber, is understood as meaning in particular a compound that absorbs light in a defined wavelength range. An absorber layer is accordingly understood as meaning in particular a layer in an optoelectronic component that comprises at least one absorber material.

Numerous polymeric and non-polymeric absorber materials for organic photovoltaic elements in the red and near infrared (NIR) spectral range between 600 nm and 1400 nm are known from the prior art. In the field of non-polymeric absorber materials, materials of the BODIPYs substance class in particular have been found to be suitable for the near-infrared spectral range.

Umezawa et al. (“Bright, Color-Tunable Fluorescent Dyes in the Visible-Near-Infrared Region”, J. Am. Chem. Soc., 2008, 130, 5, 1550-1551) discloses BODIPY structures as fluorescent dyes that are unsubstituted in the meso position or bear a fluorinated alkyl chain.

Li et al. (“Small Molecule Near-Infrared Boron Dipyrromethene Donors for Organic Tandem Solar Cells”, J. Am. Chem. Soc., 2017, 139, 13636-13639) discloses BODIPY structures that bear perfluorinated alkyl chains in the meso position and can be used as NIR donor materials in organic solar cells.

The absorbers in the red and near-infrared spectral range known from the prior art are thus unsatisfactory. Although the known absorber materials are suitable for photoactive layers in organic photovoltaic elements, i.e. organic solar cells, there is a need for improvement in the absorption properties of the absorber materials. The efficiency of an organic photovoltaic element depends on factors including the absorption behavior of the organic materials, i.e. the absorber materials, in the photoactive layer. There is a particular need for absorber materials, in particular donors, having a steep absorption edge for use in NIR subcells of tandem or multijunction solar cells. In order to avoid parasitic absorption with an adjoining subcell, the absorption band of the NIR absorber should preferably not extend too far into the red spectral range. Absorber materials having relatively low parasitic absorption to the red subcell together alongside a relatively steep absorption spectrum are particularly desirable.

### SUMMARY

The object of the invention is accordingly to provide a chemical compound, an optoelectronic component comprising at least one chemical compound of this type, and a use of at least one chemical compound of this type in an optoelectronic component, wherein the recited disadvantages are absent and wherein the chemical compounds in particular have improved absorption properties alongside a steep absorption edge.

The object is achieved by the subject matter of the independent claims. Advantageous configurations will be apparent from the dependent claims.

The object is achieved in particular by a chemical compound of the general formula Ia or Ib

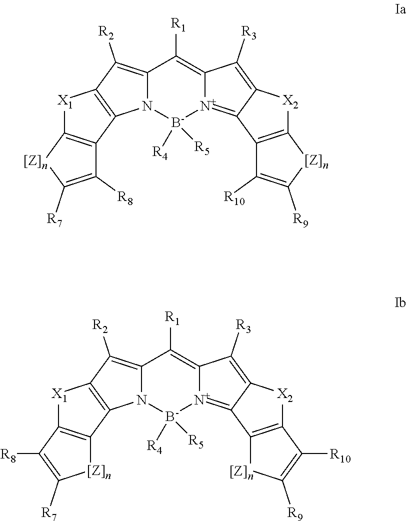

characterized in that X₁ and X₂ are each independently O, S, or NR₆, where R₆ is selected from the group consisting of H, alkyl, alkoxy, amino, aryl, and heteroaryl, R₁ is selected from the group consisting of F, fluorinated or partially fluorinated alkyl, and an aromatic heterocyclic 5-membered ring or 6-membered ring or an aromatic homocyclic 6-membered ring, R₂ and R₃ are each independently selected from the group consisting of H, halogen, CN, alkyl, alkoxy, amino, aryl and heteroaryl, R₄ and R₅ are each independently selected from the group consisting of halogen, preferably F, and fluorinated or partially fluorinated alkyl, where Z is in each case independently selected from the group consisting of O, S, CH₂, CHR₁₁, CR₁₂R₁₃, SiHR₁₁, SiR₁₂R₁₃, NH, NR₁₄, PR₁₅, where R₁₁, R₁₂, R₁₃, R₁₄, and R₁₅ are each independently selected from the group consisting of halogen, alkyl, alkoxy, amino, aryl, and heteroaryl, where n is independently 1 or 2, where R₇ and R₈ and/or R₉ and R₁₀ in each case together form a heterocyclic 5-membered ring or 6-membered ring having at least one heteroatom selected from the group consisting of O, S, N, Si or P, or form a homocyclic 6-membered ring, it being possible for the heterocyclic 5-membered ring or 6-membered ring or homocyclic 6-membered ring to be fused to further rings in each case.

According to the invention, the molecular structure of BODIPY compounds in particular is made more rigid by introducing a bridging unit between the BODIPY core and the two lateral units, in particular by means of a 5-membered ring or 6-membered ring between the BODIPY core and each of the two lateral units, wherein the BODIPY core is in particular fused on either side with the lateral unit comprising at least two rings. The resulting rigidification or planarization of molecular structures in BODIPY compounds leads to steeper absorption edges and red-shifted absorption maxima.

A substitution is understood as meaning in particular the replacement of H with a substituent. A substituent is understood as meaning in particular all atoms and atomic groups except hydrogen, preferably a halogen, an alkyl group, where the alkyl group may be linear or branched, an alkenyl group, an alkynyl group, an amino group, an alkoxy group, a thioalkoxy group, an aryl group, or a heteroaryl group. A halogen is understood as meaning in particular F, Cl or Br, preferably F.

A heteroatom is understood as meaning in particular an atom selected from the group consisting of O, S, Se, Si, B, N or P, preferably selected from the group consisting of O, S, or N.

The chemical compounds of the invention have advantages by comparison with the prior art. Advantageously, it is possible to provide improved absorber materials, in particular donors, for optoelectronic components. Advantageously, the compounds have a steep absorption edge in the region greater than 850 nm, preferably greater than 870 nm, more preferably greater than 900 nm, and are therefore particularly suitable for use in subcells of tandem or multijunction solar cells. The absorption edge of the bridged chemical compounds has a steeper course, particularly in comparison with corresponding unbridged compounds. Advantageously absorber materials for the red and near-infrared spectral range that have a steep absorption edge are provided, which particularly show relatively low parasitic absorption in a subcell of a tandem or multijunction cell; preferably, the absorption of the compounds does not extend far into the NIR region. Overlap with the absorption region of the red subcell is advantageously reduced. The compounds of the invention advantageously have particularly good evaporability.

In the context of the invention and as opposed to an unbridged compound, a bridged chemical compound is understood as meaning a BODIPY compound having a bridging unit between the BODIPY core and each of the two lateral units of the BODIPY core, in particular by means of a 5-membered ring or 6-membered ring between the BODIPY core and each of the two lateral units, wherein the BODIPY core is in particular fused on either side with a lateral unit comprising at least two rings.

An absorption edge is understood as meaning in particular an abrupt transition from weak to stronger absorption that occurs at a particular point in an electromagnetic spectrum.

According to one development of the invention, R₁ is selected from the group consisting of F, CF₃, C₂F₅, and an aromatic heterocyclic 5-membered ring or 6-membered ring or an aromatic homocyclic 6-membered ring in which preferably at least one hydrogen atom is substituted by F, Cl and/or CF₃, preferably an aromatic heterocyclic 6-membered ring or an aromatic homocyclic 6-membered ring in which at least two hydrogen atoms are substituted by F, Cl and/or CF₃.

According to one development of the invention, R₇ and R₈ and/or R₉ and R₁₀ in each case together form an aromatic homocyclic 6-membered ring in which preferably at least one hydrogen atom of the homocyclic 6-membered ring is substituted by halogen, alkyl, alkoxy, aryl or heteroaryl and/or in which the homocyclic 6-membered ring is not fused to further rings.

According to one development of the invention, R₇ and R₈ and/or R₉ and R₁₀ in each case together form an aromatic heterocyclic 5-membered ring or 6-membered ring having at least one heteroatom selected from the group consisting of O, S, N, Si or P in which preferably at least one hydrogen atom of the heterocyclic 5-membered ring or 6-membered ring is substituted by halogen, alkyl, alkoxy, aryl or heteroaryl and/or in which the heterocyclic 5-membered ring or 6-membered ring is not fused to further rings.

In a preferred embodiment of the invention, R₇ and R₈ and/or R₉ and R₁₀ in each case together form a heterocyclic 5-membered ring or 6-membered ring having at least one heteroatom selected from O, S or N, wherein the heterocyclic 5-membered ring or 6-membered ring is preferably unsubstituted, or a homocyclic 6-membered ring.

In a preferred embodiment of the invention, X₁ is the same as X₂.

In a preferred embodiment of the invention, R₂ and R₃ are H or alkyl, preferably H, methyl, ethyl or propyl.

In a preferred embodiment of the invention, R₄ and R₅ are selected from the group consisting of F and CF₃, particularly preferably R₄ and R₅ are F.

According to one development of the invention, R₂ is the same as R₃, R₄ is the same as R₅, and/or R₇ and R₈ are the same as R₉ and R₁₀.

In a preferred embodiment of the invention, Z and n are in each case the same.

In a preferred embodiment of the invention, R₇ is the same as R₉ and R₈ is the same as R₁₀.

In a preferred embodiment of the invention, R₁ is a heterocyclic 5-membered ring or 6-membered ring containing at least one sp2-hybridized nitrogen atom having a free electron pair in the ring system, preferably R₁ is selected from the group consisting of substituted or unsubstituted imidazole, pyrazole, triazole, tetrazole, pyridine, pyrimidine, pyrazine, pyridazine, triazine, oxazole, isoxazole, thiazole, and isothiazole.

According to one development of the invention, the chemical compound has the general formula IIa, IIb, IIc and/or IId:

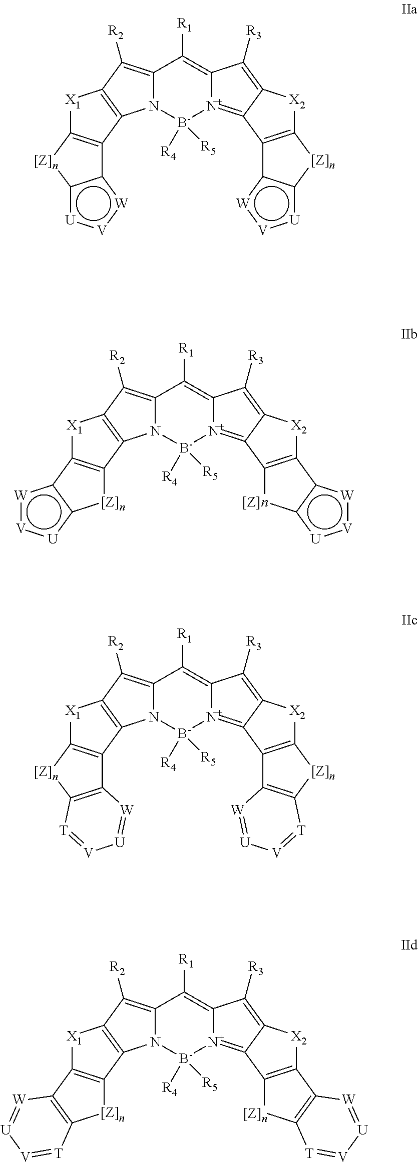

wherein U, V, and W in formula IIa and IIb are each independently selected from the group consisting of CR₁₆, O, S, N, NR₁₇, where R₁₆ and R₁₇ are each independently selected from the group consisting of H, halogen, alkyl, alkoxy, alkylthiooxy, amino, aryl, and heteroaryl, where T, U, V, and W in formula IIc and IId are each independently selected from the group consisting of CH, CR₁₈, and N, where R₁₈ is in each case independently selected from the group consisting of halogen, alkyl, alkoxy, alkylthiooxy, amino, aryl, and heteroaryl, wherein U, V, and W in formula IIa and IIb or T, U, V, and W in formula IIc and IId may be fused to a heterocyclic 5-membered ring or 6-membered ring having at least one heteroatom selected from the group consisting of O, S, and N or a homocyclic 6-membered ring, where Z is in each case independently selected from the group consisting of O, S, CH₂, CHR₁₁, CR₁₂R₁₃, SiHR₁₁, SiR₁₂R₁₃, NH, NR₁₄, PR₁₅, where R₁₁, R₁₂, R₁₃, R₁₄, and R₁₅ are each independently selected from the group consisting of alkyl, alkoxy, amino, aryl, and heteroaryl, and where n is in each case independently 1 or 2.

In a preferred embodiment of the invention, X₁ and X₂ are O or S, R₂ and R₃ are H, and R₄ and R₅ are F.

According to one development of the invention, at least one U, V, and W in formula IIa and IIb is an O or S, preferably U or W, wherein T, U, V, and W in formula IIc and IId are each independently selected from the group consisting of CH and CR₁₈, where R₁₈ is in each case independently selected from the group consisting of alkyl, alkoxy, aryl, and heteroaryl, and/or wherein at least U or V in formula IIc and IId is CR₁₈, where R₁₈ is selected from the group consisting of alkyl, alkoxy, aryl, and heteroaryl, or T, U, V, and W in formula IIc and IId are each independently CH or CR₁₈, where R₁₈ is alkyl, preferably T, U, V, and W in formula IIc and IId are H.

In a preferred embodiment of the invention, at least one further homocyclic or heterocyclic 5-membered ring or 6-membered ring is fused to U, V, W in formula IIa or IIb or to T, U, V, W in formula IIc or IId, preferably an aromatic heterocyclic 5-membered ring or 6-membered ring or an aromatic homocyclic 6-membered ring.

In a preferred embodiment of the invention, X1 and/or X2 in each case together with R₁₁, R₁₂, R₁₃, R₁₄ or R₁₅ form a heterocyclic five-membered ring or six-membered ring having at least one heteroatom selected from the group consisting of O, S, and N, or a homocyclic six-membered ring, preferably a heterocyclic 5-membered ring.

According to one development of the invention, Z is in each case independently selected from the group consisting of O, S, CH₂, CHR₁₁, CR₁₂R₁₃, SiHR₁₁, SiR₁₂R₁₃, NH, NR₁₄, PR₁₅, where R₁₁, R₁₂, R₁₃, R₁₄, and R₁₅ are each independently selected from the group consisting of alkyl, alkoxy, preferably alkyl, or Z is in each case independently selected from the group consisting of O, S, CH₂, CHR₁₁, and CR₁₂R₁₃, where R₁₁, R₁₂, and R₁₃ are each independently selected from the group consisting of alkyl, aryl, and heteroaryl, and/or where n is 1.

In a particularly preferred embodiment of the invention, Z is selected from the group consisting of CH₂, CHR₁₁, CR₁₂R₁₃, where R₁₁, R₁₂, and R₁₃ are each independently an alkyl, preferably methyl, ethyl, propyl or isopropyl.

According to one development of the invention, R₄ and R₅ are F, and/or X₁ and X₂ are each O or S.

According to one development of the invention, R₂ and R₃ are each independently selected from the group consisting of H, alkyl, alkoxy, aryl, and heteroaryl, where R₂ and R₃ are preferably H or alkyl, particularly preferably H, methyl, ethyl, or propyl.

According to one development of the invention, Z is selected from CH₂, CHR₁₁, and CR₁₂R₁₃, where R₁₁, R₁₂, and R₁₃ are each independently selected from the group consisting of alkyl, alkoxy, aryl and heteroaryl, preferably H or alkyl, and/or where n is 1.

In an alternative preferred embodiment of the invention, the rings in formulas IIa, IIb, IIc and IId are not fused to further rings.

In a preferred embodiment of the invention, the chemical compound is mirror-symmetrical in respect of the axis through R₁ and B.

According to one development of the invention, the chemical compound is selected from the group consisting of:

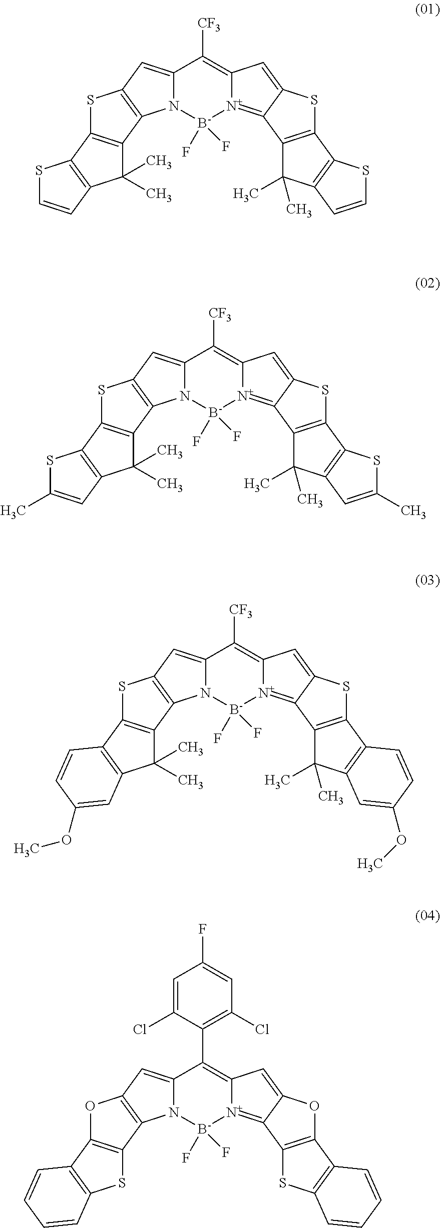

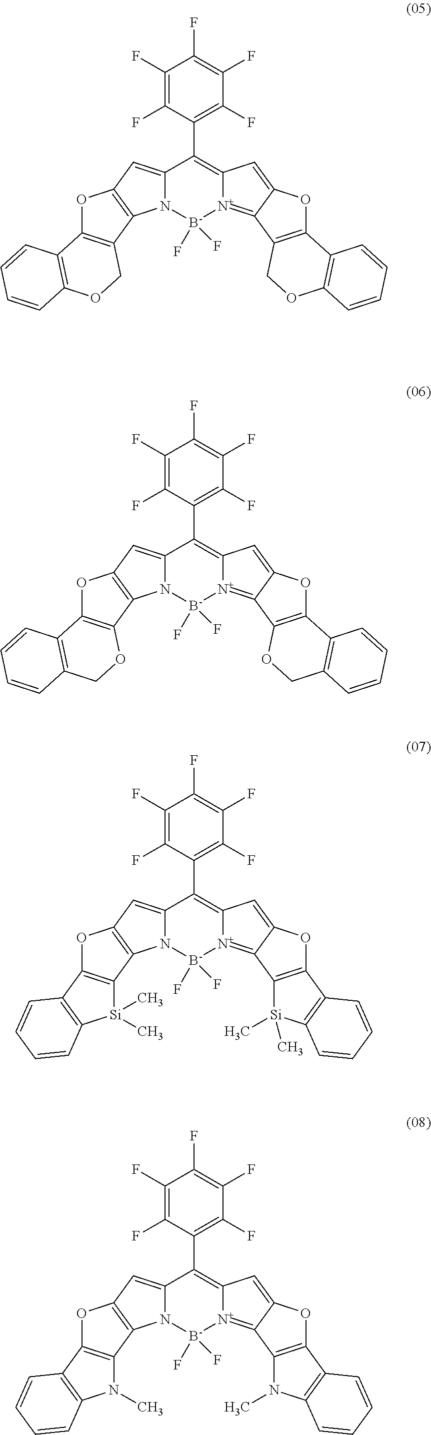 [SMILES: Fc1c(F)c(F)c(C2=C3C=c4oc5c(c4=[N+]3[B-](F)(F)n3c2cc2oc4c(c23)COc2ccccc2-4)COc2ccccc2-5)c(F)c1F ; Fc1c(F)c(F)c(C2=C3C=c4oc5c(c4=[N+]3[B-](F)(F)n3c2cc2oc4c(c23)OCc2ccccc2-4)OCc2ccccc2-5)c(F)c1F ; C[Si]1(C)c2ccccc2-c2oc3c(c21)=[N+]1C(=C(c2c(F)c(F)c(F)c(F)c2F)c2cc4oc5c(c4n2[B-]1(F)F)[Si](C)(C)c1ccccc1-5)C=3 ; Cn1c2ccccc2c2oc3c(c21)=[N+]1C(=C(c2c(F)c(F)c(F)c(F)c2F)c2cc4oc5c6ccccc6n(C)c5c4n2[B-]1(F)F)C=3]

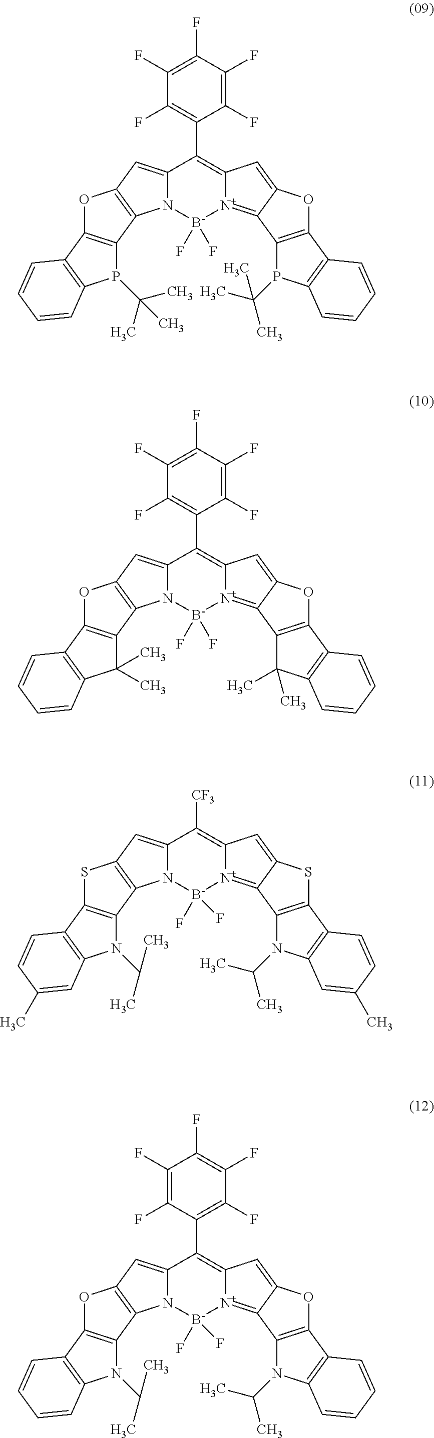 [SMILES: CC(C)(C)p1c2ccccc2c2oc3c(c21)=[N+]1C(=C(c2c(F)c(F)c(F)c(F)c2F)c2cc4oc5c6ccccc6p(C(C)(C)C)c5c4n2[B-]1(F)F)C=3 ; CC1(C)c2ccccc2-c2oc3c(c21)=[N+]1C(=C(c2c(F)c(F)c(F)c(F)c2F)c2cc4oc5c(c4n2[B-]1(F)F)C(C)(C)c1ccccc1-5)C=3 ; Cc1ccc2c3sc4c(c3n(C(C)C)c2c1)=[N+]1C(=C(C(F)(F)F)c2cc3sc5c6ccc(C)cc6n(C(C)C)c5c3n2[B-]1(F)F)C=4 ; CC(C)n1c2ccccc2c2oc3c(c21)=[N+]1C(=C(c2c(F)c(F)c(F)c(F)c2F)c2cc4oc5c6ccccc6n(C(C)C)c5c4n2[B-]1(F)F)C=3]

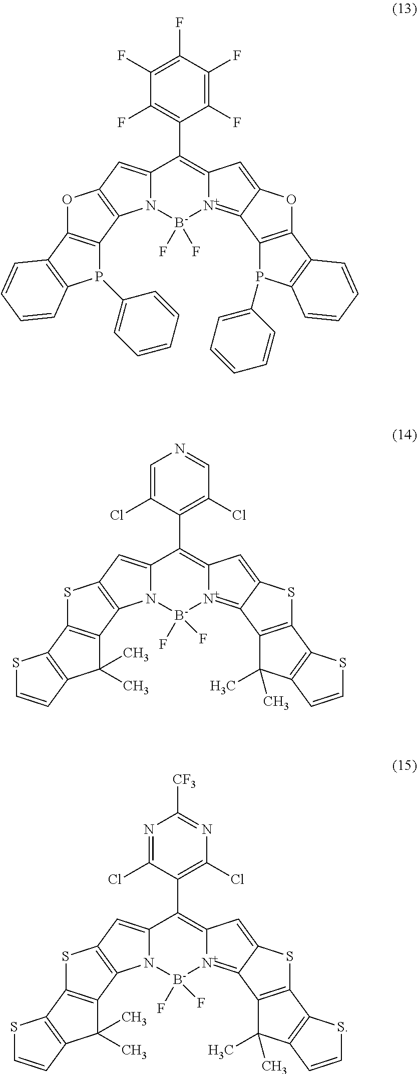 [SMILES: Fc1c(F)c(F)c(C2=C3C=c4oc5c6ccccc6p(-c6ccccc6)c5c4=[N+]3[B-](F)(F)n3c2cc2oc4c5ccccc5p(-c5ccccc5)c4c23)c(F)c1F ; CC1(C)c2ccsc2-c2sc3c(c21)=[N+]1C(=C(c2c(Cl)cncc2Cl)c2cc4sc5c(c4n2[B-]1(F)F)C(C)(C)c1ccsc1-5)C=3 ; CC1(C)c2ccsc2-c2sc3c(c21)=[N+]1C(=C(c2c(Cl)nc(C(F)(F)F)nc2Cl)c2cc4sc5c(c4n2[B-]1(F)F)C(C)(C)c1ccsc1-5)C=3]

The chemical compounds of the invention relate in particular to “small molecules”. Small molecules are understood as meaning in particular non-polymeric organic molecules having monodisperse molar masses of between 100 and 2000 g/mol that are in the solid phase at standard pressure (air pressure of the ambient atmosphere) and at room temperature. In particular, the small molecules are photoactive, photoactive being understood as meaning that the molecules undergo a change of charge state and/or of polarization state when exposed to light. The photoactive molecules in particular show an absorption of electromagnetic radiation within a defined wavelength range, wherein absorbed electromagnetic radiation, i.e. photons, is converted into excitons. In a preferred embodiment of the invention, the chemical compound has a molecular weight of 300-1500 g/mol.

The object of the present invention is also achieved by providing an optoelectronic component comprising a first electrode, a second electrode, and a layer system, the layer system being arranged between the first electrode and the second electrode, in particular according to one of the exemplary embodiments described above. In the optoelectronic component, at least one layer of the layer system comprises at least one chemical compound of the invention. For the optoelectronic component comprising the at least one chemical compound, this gives rise in particular to the advantages already elucidated in connection with the chemical compound of the invention.

According to one development of the invention, the optoelectronic component comprises a layer system having at least one photoactive layer, preferably a light-absorbing photoactive layer, wherein the at least one photoactive layer comprises the at least one chemical compound.

In a preferred embodiment of the invention, the at least one photoactive layer is an absorber layer; preferably, the at least one chemical compound is an absorber material, particularly preferably a donor.

In a preferred embodiment of the invention, the layer system comprises at least two photoactive layers, preferably at least three photoactive layers, or preferably at least four photoactive layers.

According to one development of the invention, the optoelectronic component is an organic photovoltaic element, an OFET (organic field-effect transistor), an OLED (organic light-emitting diode), or an organic photodetector. An organic photovoltaic element permits the conversion of electromagnetic radiation, particularly in the visible light wavelength range, into electrical current through utilization of the photoelectric effect. In this context, the term “photoactive” is understood as meaning the conversion of light energy into electrical energy.

The object of the present invention is also achieved by providing a use of a chemical compound of the invention in an optoelectronic component, in particular according to one of the exemplary embodiments described above. The use of the chemical compound in an optoelectronic component gives rise in particular to the advantages that have already been elucidated in connection with the chemical compound of the invention and with the optoelectronic component comprising the at least one chemical compound.

According to a further development of the invention, the chemical compound of the invention is used in an organic photovoltaic element, an OFET (organic field-effect transistor), an OLED (organic light-emitting diode), or an organic photodetector.

In a preferred embodiment of the invention, the at least one chemical compound of the invention is used as absorber material in a photoactive layer of the optoelectronic component. In a preferred embodiment of the invention, the chemical compound of the invention is used as donor in a donor-acceptor heterojunction.

In a preferred embodiment of the invention, the layer system of the optoelectronic component comprises at least one transport layer, wherein the at least one transport layer is doped, partially doped or undoped; preferably, the layer system comprises at least one electron-transport layer (ETL) and at least one hole-transport layer (HTL).

In a preferred embodiment of the invention, the chemical compound and/or a layer comprising the at least one chemical compound are deposited by means of vacuum processing, gas-phase deposition or solvent processing, particularly preferably by means of vacuum processing.

### BRIEF DESCRIPTION OF THE DRAWINGS

The invention will be elucidated more particularly hereinbelow with reference to the drawings. In the figures:

FIG. 1 shows a schematic representation of an exemplary embodiment of an optoelectronic component in cross section;

FIG. 2 shows a graphical representation of absorption spectra of inventive and noninventive compounds of the invention;

FIG. 3 shows a graphical representation of the current-voltage curve, the spectral external quantum yield, and the fill factor of a BHJ cell comprising compound (02), measured on an organic optoelectronic component;

FIG. 4 shows a graphical representation of the current-voltage curve, the spectral external quantum yield, and the fill factor of a BHJ cell comprising compound (03), measured on an organic optoelectronic component;

FIG. 5 shows a graphical representation of the current-voltage curve, the spectral external quantum yield, and the fill factor of a BHJ cell comprising compound (12), measured on an organic optoelectronic component; and

FIG. 6 shows a graphical representation of the current-voltage curve, the spectral external quantum yield, and the fill factor of a PHJ cell comprising compound (12), measured on an organic optoelectronic component.

### DETAILED DESCRIPTION

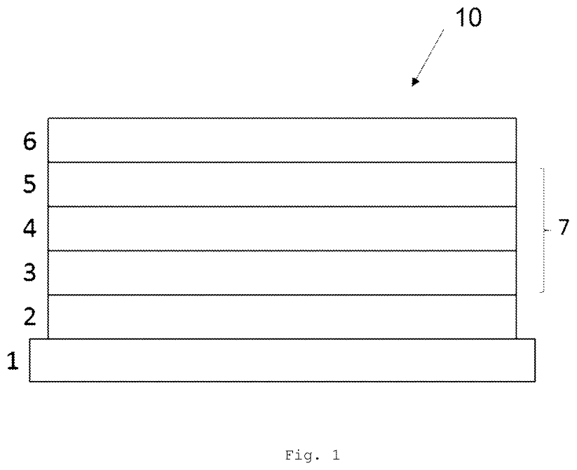

FIG. 1 shows a schematic representation of an exemplary embodiment of an optoelectronic component in cross section. The optoelectronic component 10 comprises here at least one chemical compound of the general formula Ia or Ib.

The optoelectronic component 10 comprises a first electrode 2, a second electrode 6, and a layer system 7, the layer system 7 being arranged between the first electrode 2 and the second electrode 6.

At least one layer of the layer system 7 here comprises at least one chemical compound of the invention.

In one configuration of the invention, the optoelectronic component 10 comprises a layer system 7 having at least one photoactive layer 4, preferably a light-absorbing photoactive layer 4, wherein the at least one photoactive layer 4 comprises the at least one chemical compound. The optoelectronic component 10 may be an organic photovoltaic element, an OFET (organic field-effect transistor), an OLED (organic light-emitting diode), or an organic photodetector.

In this exemplary embodiment, the optoelectronic component 10 is an organic photovoltaic element.

In this exemplary embodiment, the organic photovoltaic element comprises a layer system 7 having at least one photoactive layer 4, preferably a light-absorbing photoactive layer 4, wherein the at least one photoactive layer 4 comprises the at least one compound of the invention.

In one exemplary embodiment, the organic photovoltaic element comprises a substrate 1, made for example of glass, on which is located an electrode 2, made for example of ITO. Arranged thereon is the layer system 7 having an electron-transporting layer 3 (ETL) and a photoactive layer 4 comprising at least one compound of the invention as p-conducting donor material, and an n-conducting acceptor material, for example C60 fullerene. The photoactive layer 4 may be formed either as a planar heterojunction (PHJ) or as a bulk heterojunction (BHJ). Arranged above is a p-doped hole-transport layer 5 (HTL) and an electrode 6 made of gold or aluminum.

In a further configuration of the invention, the photoactive layer 4 is formed as a mixed layer composed of the at least one compound of the invention and at least one further compound, or as a mixed layer of the at least one compound of the invention and at least two further compounds, the compounds being absorber materials.

In a further configuration of the invention, the layer system 7 comprises at least two photoactive layers 4, preferably at least three photoactive layers 4, or preferably at least four photoactive layers 4.

In a further configuration of the invention, the optoelectronic component 10 is formed as a tandem cell, triple cell or multiple cell. In this case, two or more photoactive layers 4 are stacked on top of one other, the photoactive layers 4 being constructed of the same or different materials or material mixtures.

The individual of an optoelectronic component 10 of the invention can be produced by vaporization under reduced pressure, with or without carrier gas, or by processing a solution or suspension, for example coating or printing. Individual layers can also be applied by sputtering. This is possible in particular for the base contact.

It is advantageous to produce the layers by vaporization under reduced pressure, for which the support substrate may be heated.

The general preparation of the compounds of the invention is known from the prior art to those skilled in the art. Reference in this connection is made in particular to international applications WO 2007/126052 A1.

The chemical compound of the general formula Ia or Ib has the following structure:

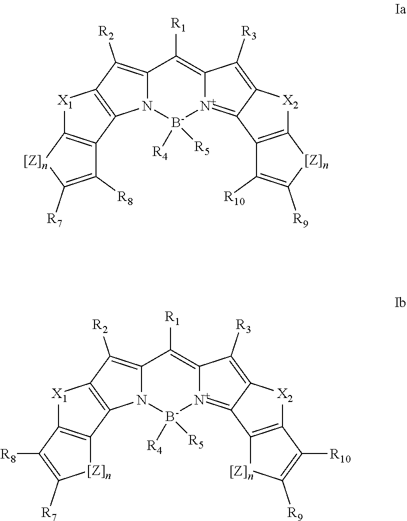

wherein X₁ and X₂ are each independently O, S, or NR₆, where R₆ is selected from the group consisting of H, alkyl, alkoxy, amino, aryl, and heteroaryl, R₁ is selected from the group consisting of F, fluorinated or partially fluorinated alkyl, and an aromatic heterocyclic 5-membered ring or 6-membered ring or an aromatic homocyclic 6-membered ring, R₂ and R₃ are each independently selected from the group consisting of H, halogen, CN, alkyl, alkoxy, amino, aryl, and heteroaryl, R₄ and R₅ are each independently selected from the group consisting of halogen, preferably F, and fluorinated or partially fluorinated alkyl, where Z is in each case independently selected from the group consisting of O, S, CH₂, CHR₁₁, CR₁₂R₁₃, SiHR₁₁, SiR₁₂R₁₃, NH, NR₁₄, PR₁₅, where R₁₁, R₁₂, R₁₃, R₁₄, and R₁₅ are each independently selected from the group consisting of halogen, alkyl, alkoxy, amino, aryl, and heteroaryl, where n is in each case independently 1 or 2, wherein R₇ and R₈ and/or R₉ and R₁₀ in each case together form a heterocyclic 5-membered ring or 6-membered ring having at least one heteroatom selected from the group consisting of O, S, N, Si or P, or form a homocyclic 6-membered ring, it being possible for the heterocyclic 5-membered ring or 6-membered ring or homocyclic 6-membered ring to be fused to further rings in each case.

In one configuration of the invention, R₁ is selected from the group consisting of F, CF₃, C₂F₅, and an aromatic heterocyclic 5-membered ring or 6-membered ring or an aromatic homocyclic 6-membered ring in which preferably at least one hydrogen atom is substituted by F, Cl and/or CF₃, preferably an aromatic heterocyclic 6-membered ring or an aromatic homocyclic 6-membered ring in which at least two hydrogen atoms are substituted by F, Cl and/or CF₃.

In a further configuration of the invention, R₇ and R₈ and/or R₉ and R₁₀ in each case together form an aromatic homocyclic 6-membered ring in which preferably at least one hydrogen atom of the homocyclic 6-membered ring is substituted by halogen, alkyl, alkoxy, aryl or heteroaryl and/or where the homocyclic 6-membered ring is not fused to further rings.

In a further configuration of the invention, R₇ and R₈ and/or R₉ and R₁₀ in each case together form an aromatic heterocyclic 5-membered ring or 6-membered ring having at least one heteroatom selected from the group consisting of O, S, N, Si or P in which preferably at least one hydrogen atom of the heterocyclic 5-membered ring or 6-membered ring is substituted by halogen, alkyl, alkoxy, aryl or heteroaryl and/or where the heterocyclic 5-membered ring or 6-membered ring is not fused to further rings.

In a further configuration of the invention, R₂ is the same as R₃, R₄ is the same as R₅, and/or R₇ and R₈ are the same as R₉ and R₁₀.

In a further configuration of the invention, the chemical compound has the general formula IIa, IIb, IIc and/or IId:

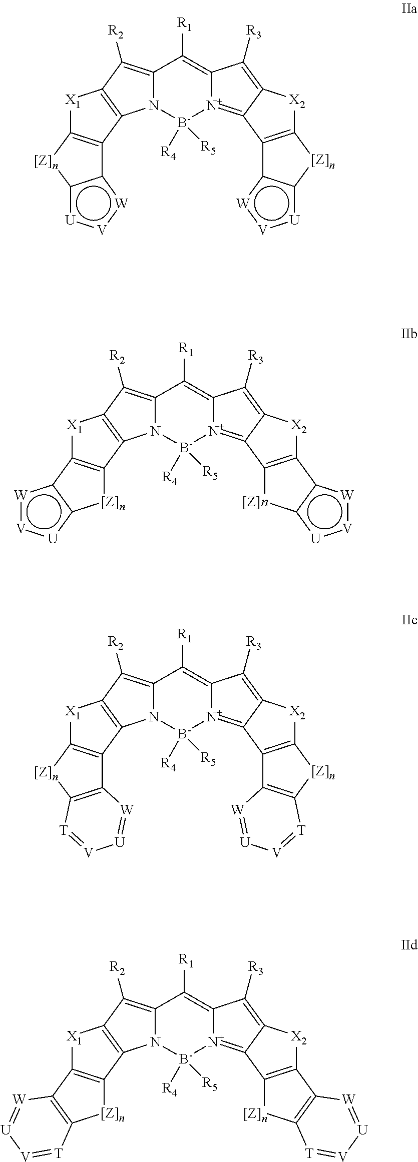

where U, V, and W in formula IIa and IIb are each independently selected from the group consisting of CR₁₆, O, S, N, NR₁₇, where R₁₆ and R₁₇ are each independently selected from the group consisting of H, halogen, alkyl, alkoxy, alkylthiooxy, amino, aryl, and heteroaryl, where T, U, V, and W in formula IIc and IId are each independently selected from the group consisting of CH, CR₁₈, and N, where R₁₈ is in each case independently selected from the group consisting of halogen, alkyl, alkoxy, alkylthiooxy, amino, aryl, and heteroaryl, wherein U, V, and W in formula IIa and IIb or T, U, V, and W in formula IIc and IId may be fused to a heterocyclic 5-membered ring or 6-membered ring having at least one heteroatom selected from the group consisting of O, S, and N or a homocyclic 6-membered ring, where Z is in each case independently selected from the group consisting of O, S, CH₂, CHR₁₁, CR₁₂R₁₃, SiHR₁₁, SiR₁₂R₁₃, NH, NR₁₄, PR₁₅, where R₁₁, R₁₂, R₁₃, R₁₄, and R₁₅ are each independently selected from the group consisting of alkyl, alkoxy, amino, aryl, and heteroaryl, and where n is in each case independently 1 or 2.

In a further configuration of the invention, at least one U, V, and W in formula IIa and IIb is an O or S, preferably U or W, and T, U, V, and W in formula IIc and IId are each independently selected from the group consisting of CH and CR₁₈, where R₁₈ is in each case independently selected from the group consisting of alkyl, alkoxy, aryl, and heteroaryl, and/or
at least U or V in formula IIc and IId is CR₁₈, where R₁₈ is selected from the group consisting of alkyl, alkoxy, aryl, and heteroaryl, or T, U, V, and W in formula IIc and IId are each independently CH or CR₁₈, where R₁₈ is alkyl; preferably, T, U, V, and W in formula IIc and IId are H.

In a further configuration of the invention, Z is in each case independently selected from the group consisting of O, S, CH₂, CHR₁₁, CR₁₂R₁₃, SiHR₁₁, SiR₁₂R₁₃, NH, NR₁₄, PR₁₅, where R₁₁, R₁₂, R₁₃, R₁₄, and R₁₅ are each independently selected from the group consisting of alkyl, alkoxy, preferably alkyl, or Z is in each case independently selected from the group consisting of O, S, CH₂, CHR₁₁ and CR₁₂R₁₃, where R₁₁, R₁₂, and R₁₃ are each independently selected from the group consisting of alkyl, aryl, and heteroaryl, and/or where n is 1.

In a further configuration of the invention, R₄ and R₅ are F, and/or X₁ and X₂ are each O or S.

In a further configuration of the invention, R₂ and R₃ are each independently selected from the group consisting of H, alkyl, alkoxy, aryl, and heteroaryl, where R₂ and R₃ are preferably H or alkyl, more preferably H, methyl, ethyl, or propyl.

In a further configuration of the invention, Z is selected from CH₂, CHR₁₁, and CR₁₂R₁₃, where R₁₁, R₁₂, and R₁₃ are each independently selected from the group consisting of alkyl, alkoxy, aryl and heteroaryl, preferably H or alkyl, and/or where n is 1.

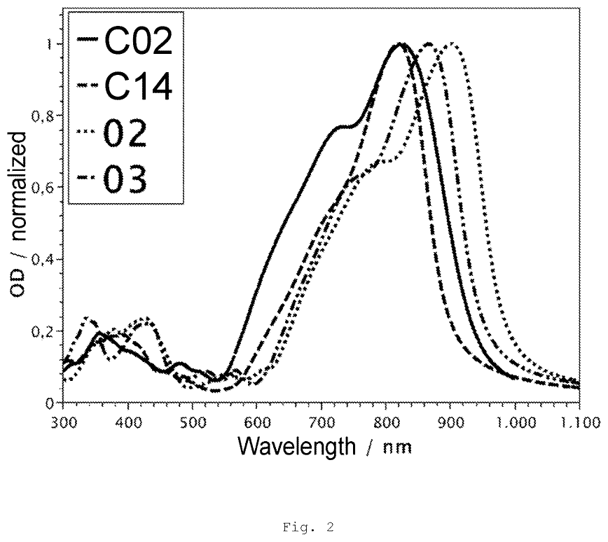

FIG. 2 shows a graphical representation of absorption spectra of inventive and noninventive compounds.

The absorption spectra of inventive compounds (2), (3), and (12) are compared with those of noninventive compounds C02 and C14. The absorption spectra (optical density over wavelength in nm) of the compounds were in each case measured for 30 nm-thick vacuum-deposited layers on quartz glass and in a dichloromethane solution.

The bridged compounds (2), (3), and (12) show a region of absorption that is shifted into the red spectral range of visible light by comparison with the unbridged compounds C02 and C14.

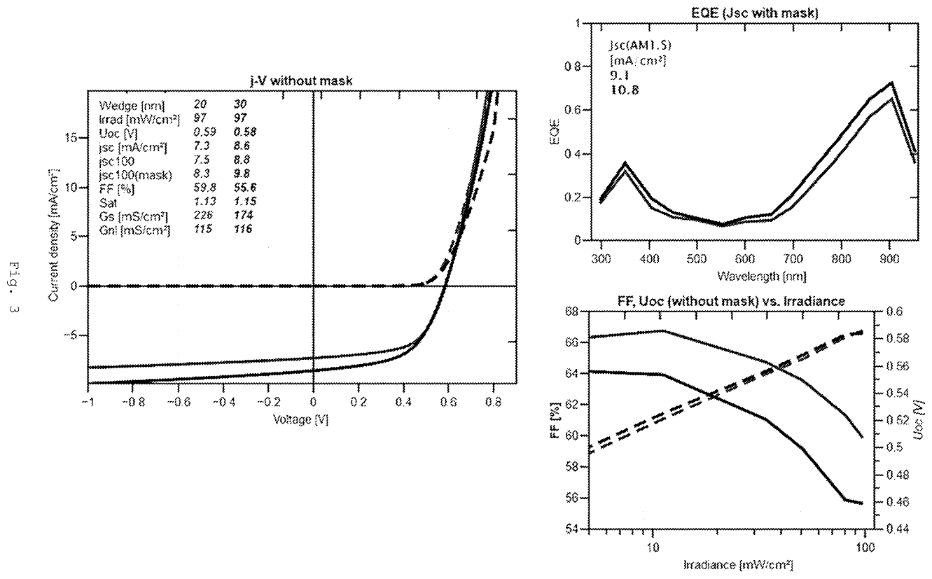

FIGS. 3 to 6 that follow show specific exemplary embodiments of organic photovoltaic elements comprising inventive chemical compounds of the general formula I.

FIG. 3 shows a graphical representation of the current-voltage curve, the spectral external quantum yield, and the fill factor of a BHJ cell comprising compound (02), measured on an organic optoelectronic component 10. In this exemplary embodiment, the optoelectronic component 10 is an organic photovoltaic element.

The current-voltage curve contains indices that characterize the organic photovoltaic element. The most important indices here are the fill factor FF, the open-circuit voltage Uoc, and the short-circuit current Jsc.

In order to examine the compounds, i.e. the use thereof as absorber materials in organic photovoltaic elements, the current-voltage curve of a BHJ cell was measured. In this exemplary embodiment, the BHJ cell on the ITO layer has a layer of C60 3 with a layer thickness of 15 nm. Onto this layer was applied compound (02) together with C60 in a thickness of 30 nm in a molar ratio of 2:3 at 90° C. as photoactive layer 4. This layer is followed by a layer of BF-DBP in a layer thickness of 10 nm followed by a layer comprising BF-DBP containing 4.1% by weight NDP9 in a layer thickness of 45 nm as a hole-transport layer 5. This layer is adjoined by a further layer comprising NDP9 in a thickness of 1 nm, followed by a gold layer in a thickness of 50 nm. ITO serves here as the electrode 2, and the neighboring fullerene C60 as the electron-transport layer (ETL) 3; this layer is adjoined by the photoactive layer 4 with C60 as electron acceptor material and the respective absorber, followed by BF-DBP as hole-transport layer (HTL) 5 and BF-DBP doped with NDP9 (Novaled AG), followed by an electrode 6 made of gold.

The current-voltage curve of a BHJ cell having the structure: ITO/C60 (15 nm)/compound (02):C60 (30 nm, 3:2, 90° C.)/BF-DBP (10 nm)/BF-DBP:NDP9 (45 nm, 4.1% by weight of NDP9)/NDP9 (1 nm)/Au (50 nm) was determined. The parameters of the cell were measured under AM1.5 illumination (AM=air mass; AM=1.5; in this spectrum, the global radiant power is 1000 W/m²; AM=1.5 as default value for measuring solar modules), wherein the photoactive layer 4 comprises a bulk heterojunction (BHJ).

In the organic photovoltaic element comprising compound (02), the fill factor FF is 55.6%, the open-circuit voltage Uoc is 0.58 V, and the short-circuit current Jsc is 10.8 mA/cm². The cell efficiency of an optoelectronic component 10 of this type, in particular a photovoltaic element, comprising compound (02) is 3.48%. Compound (02) shows good evaporability under reduced pressure.

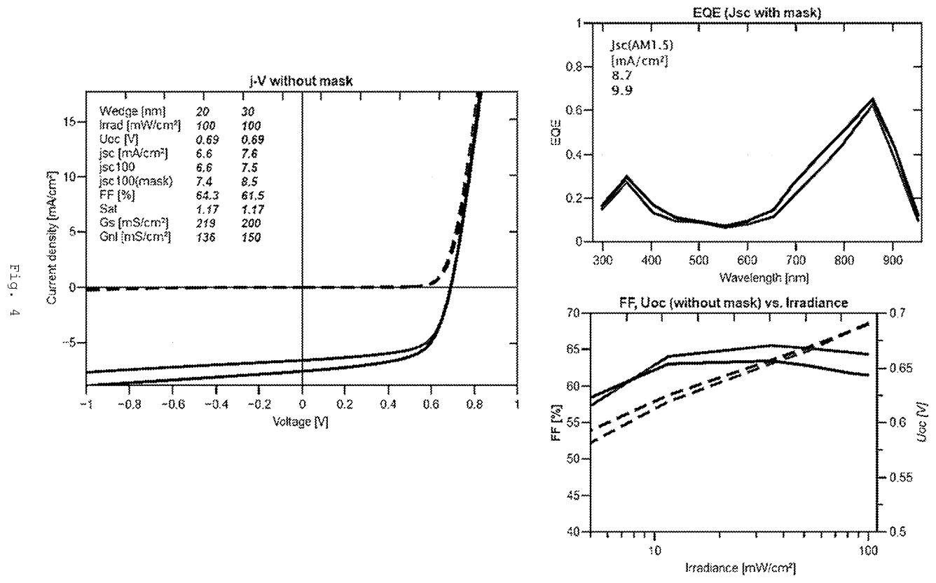

FIG. 4 shows a graphical representation of the current-voltage curve, the spectral external quantum yield, and the fill factor of a BHJ cell comprising compound (03), measured on an organic optoelectronic component 10. In this exemplary embodiment, the optoelectronic component 10 is an organic photovoltaic element. The structure of the BHJ cell corresponds to the structure of the cell from FIG. 3, in which compound (03) had been used as donor in the photoactive layer 4.

In the organic photovoltaic element comprising compound (03), the fill factor FF is 61.5%, the open-circuit voltage Uoc is 0.69 V, and the short-circuit current Jsc is 9.9 mA/cm². The cell efficiency of an optoelectronic component 10 of this type, in particular a photovoltaic element, comprising compound (03) is 4.20%. Compound (03) shows good evaporability under reduced pressure.

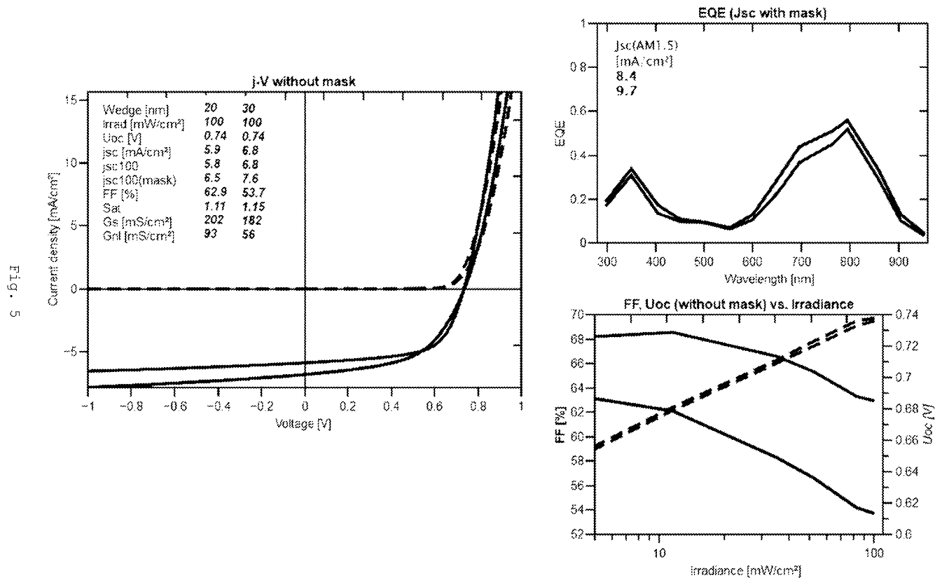

FIG. 5 shows a graphical representation of the current-voltage curve, the spectral external quantum yield, and the fill factor of a BHJ cell comprising compound (12), measured on an organic optoelectronic component 10. In this exemplary embodiment, the optoelectronic component 10 is an organic photovoltaic element. The structure of the BHJ cell corresponds to the structure of the cell from FIG. 3, in which compound (12) had been used as donor in the photoactive layer 4.

In the organic photovoltaic element comprising compound (12), the fill factor FF is 53.7%, the open-circuit voltage Uoc is 0.74 V, and the short-circuit current Jsc is 9.7 mA/cm². The cell efficiency of an optoelectronic component 10 of this type, in particular a photovoltaic element, comprising compound (12) is 3.85%. Compound (12) shows good evaporability under reduced pressure.

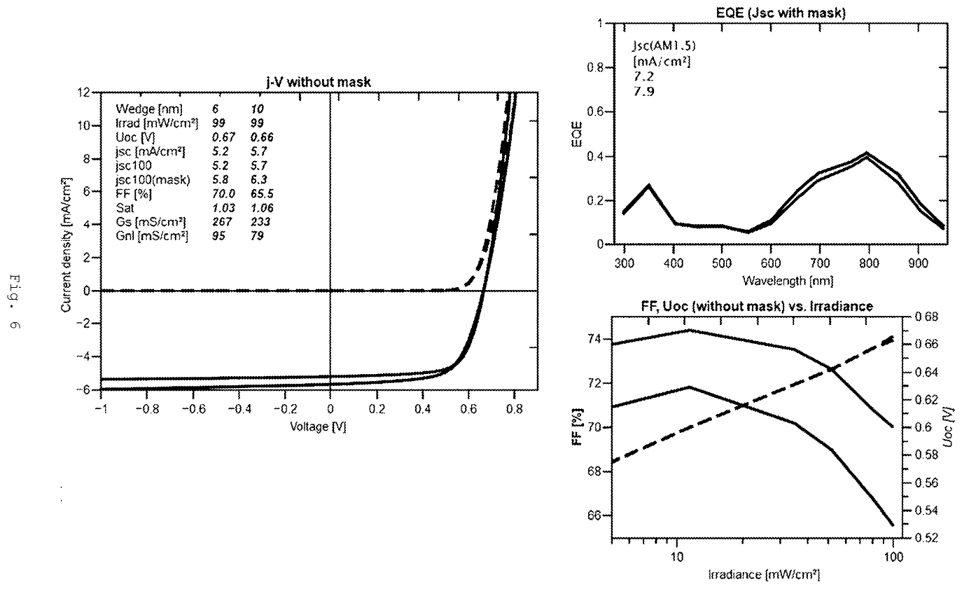

FIG. 6 shows a graphical representation of the current-voltage curve, the spectral external quantum yield, and the fill factor of a PHJ cell comprising compound (12), measured on an organic optoelectronic component 10. In this exemplary embodiment, the optoelectronic component 10 is an organic photovoltaic element.

The current-voltage curve of a PHJ cell having the structure: ITO/C60 (15 nm)/compound (12) (6 nm, 20° C.)/BF-DBP (10 nm)/BF-DBP:NDP9 (45 nm, 4% by weight NDP9)/NDP9 (1 nm)/Au (50 nm) was determined, wherein the photoactive layer 4 comprises a planar heterojunction (PHJ).

In the organic photovoltaic element comprising compound (12), the fill factor FF is 70.0%, the open-circuit voltage Uoc is 0.67 V, and the short-circuit current Jsc is 7.2 mA/cm². The cell efficiency of an optoelectronic component 10 of this type, in particular a photovoltaic element, comprising compound (12) is 3.38%.

The advantageous properties of the chemical compounds of the invention are demonstrated by their absorption properties in particular, especially by comparison with noninventive compounds, which are unbridged. Table 1 summarizes the absorption maxima and slope of compounds (01) to (15) in solution and in the film compared to noninventive compounds C02, C03, C05, and C14.

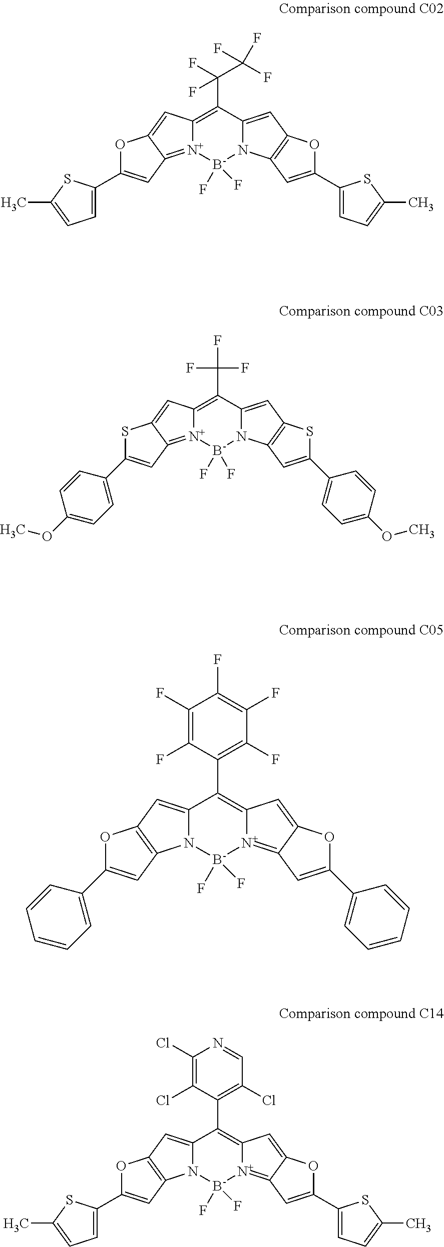

TABLE 1

| | Absorption | Absorption | |
|---|---|---|---|
| | maximum | maximum | |
| | [nm] | [nm] | Slope |
| Compound | in solution | in film | [1/eV] |
| 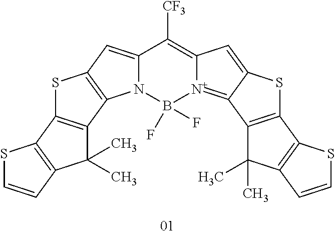 | 785 | 874 | 11.96 |
| 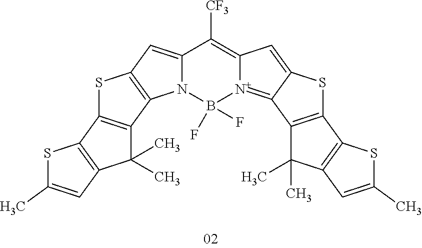 | 809 | 900 | 11.58 |
| 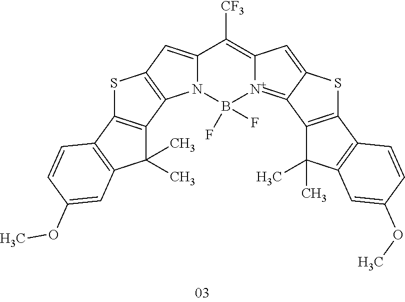 | 776 | 865 | 10.05 |
| 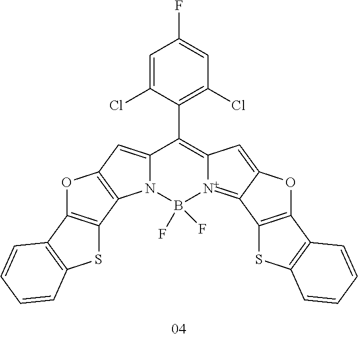 | 681 | 780 | 9.54 |
| 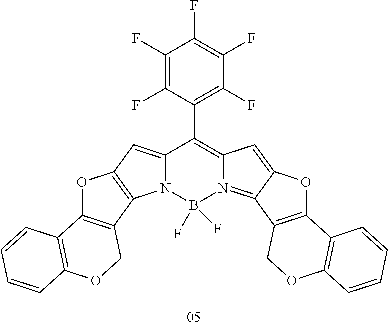 | | | |
| 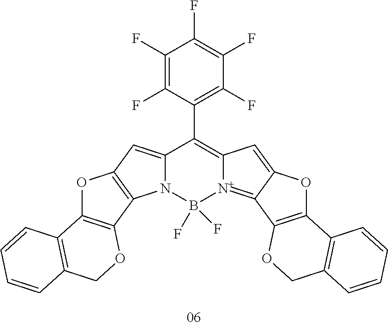 | | | |
| 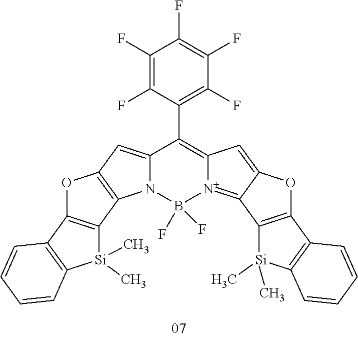 | | | |
| 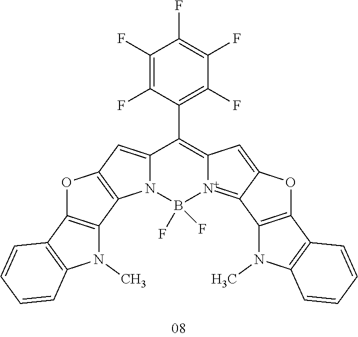 | | | |
| 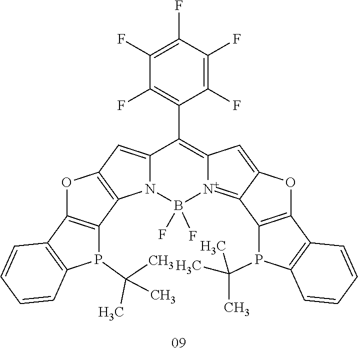 | | | |
| 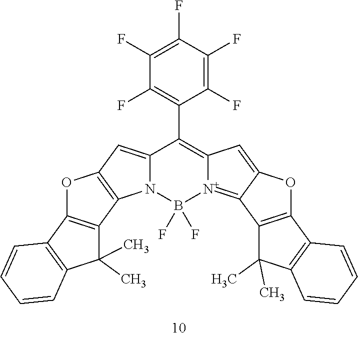 | | | |
| 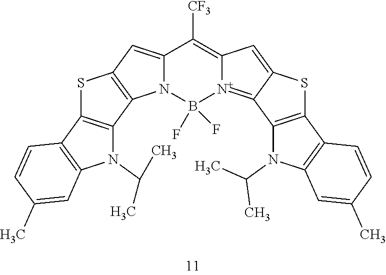 | | | |
| 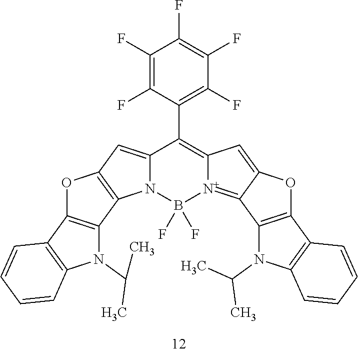 | 733 | 789 | 9.53 |
| 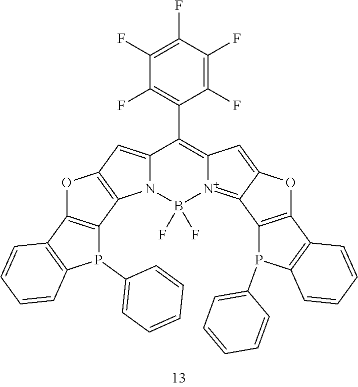 | | | |
| 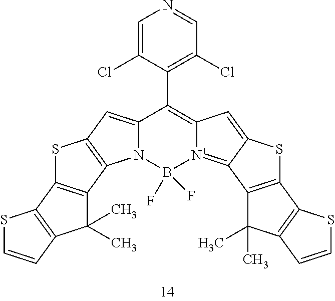 | 749 | 827 | 13.91 |
| 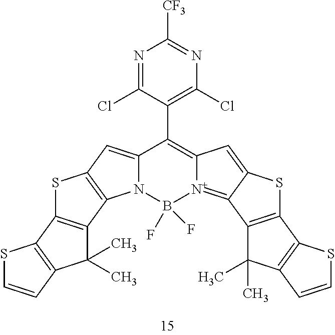 | 764 | 838 | 13.05 |
| C02 | | 822 | 6.96 |
| C03 | | 809 | 5.11 |
| C05 | | 741 | 9.14 |
| C14 | | 817 | 9.64 |

To determine the slope, the tangent at the inflection point of the long-wave absorption edge is determined. The slope is the reciprocal of the difference between the abscissa of the inflection point in eV and the zero point of the tangent in eV.

The optical properties were determined experimentally. The absorption maxima λmax were determined using a photometer in a cuvette with dichloromethane and based on 30 nm-thick vacuum vapor-deposition layers on quartz glass. Surprisingly, it was found that in the film the chemical compounds (01) to (15) have an absorption maximum that is shifted particularly far into the near-infrared spectral range, in particular above 750 nm, preferably above 780 nm, more preferably above 800 nm. In addition, the bridged chemical compounds (01) to (15) have a particularly steep absorption edge by comparison with the corresponding unbridged compound in each case.

For example, the absorption edge of cyclopentadiene-bridged compound (02) is, at 11.58 e/V, steeper than that of compound C02, at 6.96 e/V. The absorption edge of cyclopentadiene-bridged compound (03) is, at 10.05 e/V, steeper than that of compound C03, at 5.11 e/V. The pyridine-bridged compounds (08), (11), and (12), the pyran-bridged compounds (05) and (06), and the cyclopentadiene-bridged compound (10) also show steeper absorption edges than that of compound C05.

Table 2 shows the photovoltaic parameters Voc, Jsc, and FF of inventive compounds (01) to (15). The cells have the following structure:
BHJ cell: glass with ITO/C60 (15 nm)/absorber: C60 (30 nm, 3:2, 90° C.)/BF-DBP (10 nm)/BF-DBP:NDP9 (45 nm, 4% by weight NDP9)/NDP9 (1 nm)/Au (50 nm);
PHJ cell: glass with ITO/C60 (15 nm)/absorber (6 nm, 20° C.)/BF-DBP (10 nm)/BF-DBP:NDP9 (45 nm, 4% by weight NDP9)/NDP9 (1 nm)/Au (50 nm); and was measured under AMA1.5 illumination (AMA=air mass, AMA=1.5; in this spectrum, the global radiant power is 1000 W/m²; AM=1.5 as default value for measuring solar modules).
BF-DBP: hole-transport material

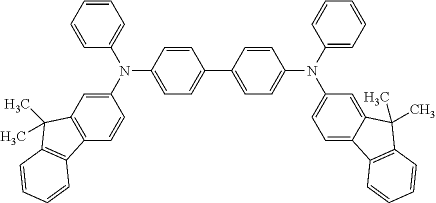 [SMILES: CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21]

TABLE 2

| | Cell | Voc | Jsc | FF | EQEₘₐₓ |
|---|---|---|---|---|---|
| Compound | type | [V] | [mA/cm²] | [%] | [%] |
| (01) * | BHJ | 0.73 | 9.4 | 58.0 | |
| (02) | BHJ | 0.58 | 10.8 | 55.6 | >70 |
| (03) | BHJ | 0.69 | 9.9 | 61.5 | >60 |
| (04) | | | | | |
| (05) | | | | | |
| (06) | | | | | |
| (07) | | | | | |
| (08) | | | | | |
| (09) | | | | | |
| (10) | | | | | |
| (11) | | | | | |
| (12) | BHJ | 0.74 | 9.7 | 53.7 | |
| (12) | PHJ | 0.67 | 7.2 | 70 | >70 |
| (13) | | | | | |
| (14) * | BHJ | 0.67 | 6.6 | 39.1 | |
| (15) | BHJ | 0.70 | 9.6 | 58.0 | |
| C02 | | | | | |
| C03 | | | | | |
| C05 | | | | | |
| C14 | | | | | |

* In the cells with compounds (01) and (014) , the hole transport material HTM081 from Merck AG was used instead of the hole transport material BF-DBP.

Compounds (01) to (15) were also found to have high thermal stability and to be vaporizable under reduced pressure without decomposition.

The experimental data of the chemical compounds of the invention with the absorption properties of the compounds and the current-voltage curves measured in organic photovoltaic elements demonstrate that the chemical compounds of the invention are very well suited for use in organic photovoltaic elements and other organic optoelectronic components.

### Synthesis

General synthesis for preparing chemical compounds of the general formula Ia or Ib is known from WO 2007/126052 A1, Bartellmess et al. (“meso-Pyridyl BODIPYs with tunable chemical, optical and electrochemical properties”, New Journal of Chemistry, 37(9), 2663-2668; 2013), and Li et al. (“Small Molecule Near-Infrared Boron Dipyrromethene Donors for Organic Tandem Solar Cells”, J. Am. Chem. Soc., 2017, 139, 13636-13639).

The following are exemplary embodiments for the synthesis of chemical compounds of the invention. The aldehydes depicted here are used to prepare the corresponding BODIPYs in accordance with Umezawa et al. (J. Am. Chem. Soc., 2008, 130, 5, 1550-1551) or Yang et al. (Chem. Commun., 2013,49, 3940-3942).

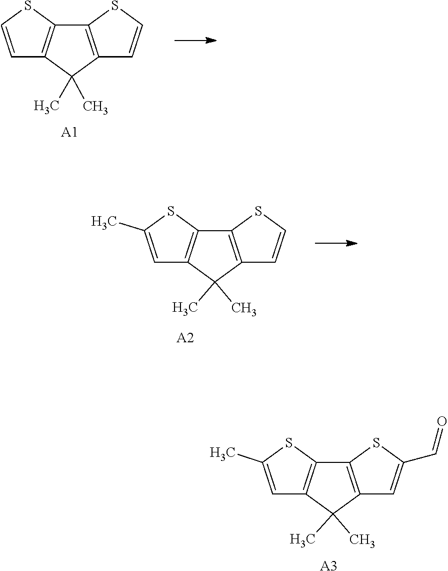

General procedure for A2: Compound A1 (1 eq.) was dissolved at −30° C. in 50 volumes of anhydrous THF (tetrahydrofuran) and treated with n-BuLi (2.5 mol/l, 1.40 eq.) added dropwise. The mixture was stirred for 30 min at −30° C., treated with methyl iodide (1.60 eq.), and then warmed overnight to 20° C. The mixture was added to a semi-concentrated ammonium chloride solution and extracted with ethyl acetate. The organic phase was washed with water and saturated NaCl solution. It was then dried over sodium sulfate, filtered, and the solvent removed under reduced pressure. Column chromatography on silica gel (eluent: DCM/PE 20:80) afforded compound A2 as a colorless solid (97%).

General procedure for A3: A solution of dimethylformamide (1.30 eq.) in 2 volumes of anhydrous DCM was treated with phosphorous oxychloride (1.20 eq.) at 0° C. and stirred at 0° C. for 30 min. This solution was then added dropwise at 0° C. to a solution of compound A2 (1 eq.) in 8 volumes of anhydrous DCM. The mixture was stirred at 20° C. for 2 h. The mixture was then treated with 25 volumes of NaOH solution (1 M) and stirred for 40 min. The organic phase was separated off and the aqueous phase extracted with DCM. The organic phases were washed with water and saturated NaCl solution. They were then dried over sodium sulfate, filtered, and the solvent removed under reduced pressure. Column chromatography on silica gel (eluent: DCM/EtOAc/PE 55:5:40) afforded compound A3 as a yellow solid (86%).

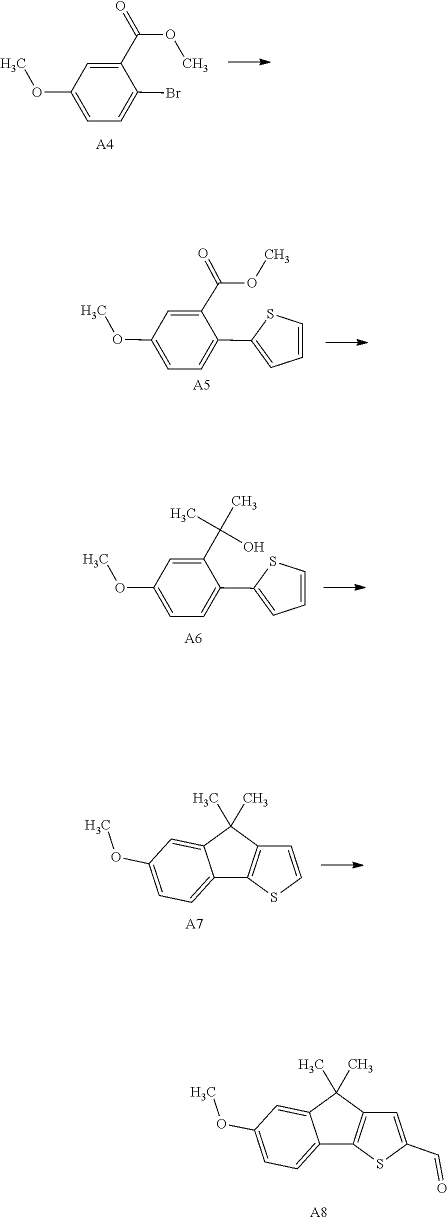

General procedure for A5: A solution of methyl 2-bromo-5-methoxybenzoate A4 (1 eq.) and 2-thiopheneboronic acid (1.10 eq.) in 10 volumes of isopropanol was treated with a solution of potassium phosphate (1.20 eq.) in 2.5 volumes of water and degassed for 20 min. Bis(tri-tert-butylphosphine)palladium(0) (0.005 eq.) was then added and the mixture was stirred at 20° C. for 2 h. The mixture was added to water and extracted 3 times with DCM. The organic phases were washed with water and saturated NaCl solution. They were then dried over sodium sulfate, filtered, and the solvent removed under reduced pressure. Column chromatography on silica gel (eluent: EtOAc) afforded compound A5 as a reddish oil (97%).

General procedure for A6: A solution of compound A5 (1 eq.) in 8 volumes of anhydrous THF was treated at −10° C. with a solution of methylmagnesium bromide (3.4 mol/L in THF) (3 eq.) added dropwise with stirring. The mixture was stirred at 40° C. for 3 h, cooled to −10° C., and treated with HCl solution (1 M, 2 eq.) added slowly. Saturated ammonium chloride solution was then added until a pH of 7-8 had been reached. The mixture was extracted 3 times with DCM. The organic phases were dried over sodium sulfate, filtered, and the solvent removed under reduced pressure. Column chromatography on silica gel (eluent: PE/EtOAc 83:17) afforded compound A6 as a yellow oil (87%).

General procedure for A7: A solution of compound A6 (1 eq.) in 30 volumes of anhydrous DCM was treated at −78° C. with methanesulfonic acid (2 eq.) added dropwise. The mixture was stirred for 30 min at −78° C., then warmed to 0° C. and treated with saturated sodium hydrogen carbonate solution. The mixture was then extracted 3 times with DCM. The organic phases were washed with water, dried over sodium sulfate, filtered, and the solvent removed under reduced pressure. Column chromatography on silica gel (eluent: PE/DCM 67:33) afforded compound A7 as a colorless oil (65%).

General procedure for A8: A solution of dimethylformamide (1.50 eq.) in 5 volumes of anhydrous DCM was treated with phosphorous oxychloride (1.50 eq.) at 0° C. and stirred at 0° C. for 30 min. This solution was then added dropwise at 0° C. to a solution of compound A7 (1 eq.) in 3 volumes of anhydrous DCM. The mixture was stirred at 20° C. for 1.5 h. The mixture was then treated with 25 volumes of NaOH solution (1 M) and stirred for 2 h. The organic phase was separated off and washed with water. It was then dried over sodium sulfate, filtered, and the solvent removed under reduced pressure. Column chromatography on silica gel (eluent: DCM) afforded compound A8 as a yellow solid (96%).

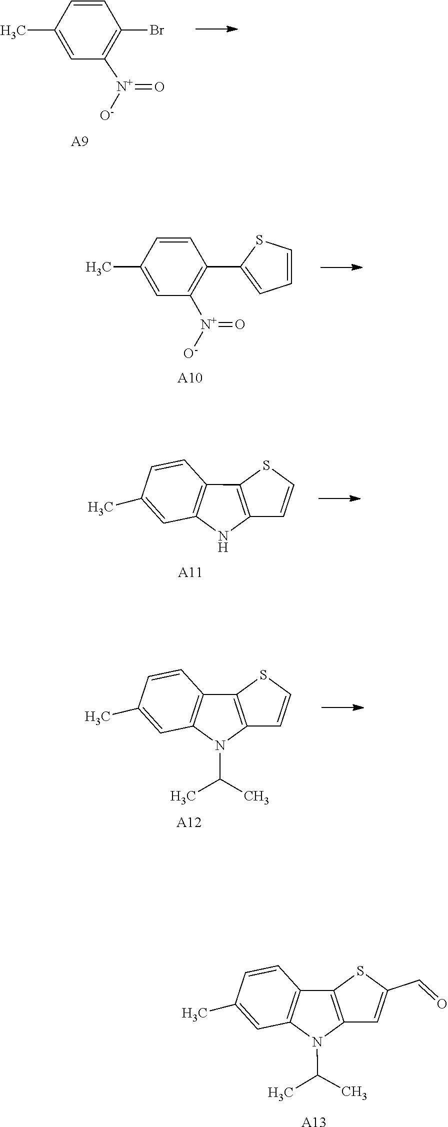

General procedure for A10: A solution of 4-bromo-3-nitrotoluene A9 (1 eq.) and 2-thiopheneboronic acid (1.10 eq.) in 18 volumes of isopropanol was treated with a solution of potassium phosphate (1.20 eq.) in 4.5 volumes of water and the mixture was degassed for 20 min. Bis(tri-tert-butylphosphine)palladium(0) (0.01 eq.) was then added and the mixture was stirred at 20° C. for 2 h. The mixture was added to water and extracted 3 times with DCM. The organic phases were washed with water and saturated NaCl solution. They were then dried over sodium sulfate, filtered, and the solvent removed under reduced pressure. Column chromatography on silica gel (eluent: PE/DCM 67:33) afforded compound A10 as a colorless oil (99%).

General procedure for A11: A solution of compound 10 (1 eq.) in triethyl phosphite (5 eq.) was stirred under reflux for 16 h. The mixture was then cooled to 20° C. and the solvent removed by distillation under reduced pressure. Column chromatography on silica gel (eluent: PE/DCM 75:25) afforded compound A11 as a colorless solid (52%).

General procedure for A12: A solution of compound A11 (1 eq.) and potassium hydroxide (2.10 eq.) in 12 volumes of anhydrous DMSO was treated with isopropyl iodide (2 eq.) and stirred at 20° C. for 2 days. The mixture was then added to water and extracted 3 times with EtOAc. The organic phases were dried over sodium sulfate, filtered, and the solvent removed under reduced pressure. Column chromatography on silica gel (eluent: PE/DCM 67:33) afforded compound A12 as a colorless solid (92%).

General procedure for A13: A solution of dimethylformamide (1.50 eq.) in 4 volumes of anhydrous DCM was treated with phosphorous oxychloride (1.60 eq.) at 0° C. and stirred at 0° C. for 40 min. This solution was then added dropwise at 0° C. to a solution of compound A12 (1 eq.) in 4 volumes of anhydrous DCM. The mixture was stirred at 20° C. for 2.5 h. The mixture was then treated with 25 volumes of NaOH solution (1 M) and stirred for 2 h. The organic phase was separated off and washed with water. It was then dried over sodium sulfate, filtered, and the solvent removed under reduced pressure. Column chromatography on silica gel (eluent: EtOAc) afforded compound A13 as a yellow solid (96%).

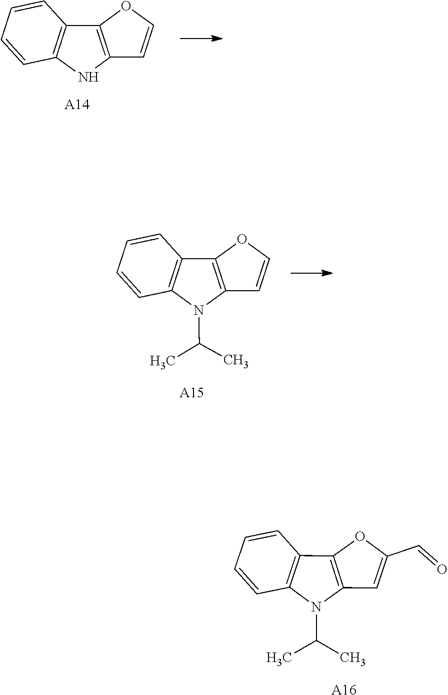

General procedure for A14: WO2022126179A1 General procedure for A15: A solution of compound A14 (1 eq.) and potassium hydroxide (2.60 eq.) in 12 volumes of anhydrous DMSO was treated with isopropyl iodide (2.50 eq.) and stirred at 20° C. for 3 h. The mixture was then added to water and extracted 3 times with EtOAc. The organic phases were dried over sodium sulfate, filtered, and the solvent removed under reduced pressure. Column chromatography on silica gel (eluent: PE/DCM 67:33) afforded compound A15 as a colorless solid (86%).

General procedure for A16: A solution of dimethylformamide (1.60 eq.) in 4 volumes of anhydrous DCM was treated with phosphorous oxychloride (1.50 eq.) at 0° C. and stirred at 0° C. for 40 min. This solution was then added dropwise at 0° C. to a solution of compound A15 (1 eq.) in 4 volumes of anhydrous DCM. The mixture was stirred at 20° C. for 1.5 h. The mixture was then treated with 30 volumes of NaOH solution (1 M) and stirred for 2 h. The organic phase was separated off and washed with water. It was then dried over sodium sulfate, filtered, and the solvent removed under reduced pressure. Column chromatography on silica gel (eluent: PE/DCM 50:50) afforded compound A16 as an orange solid (90%).

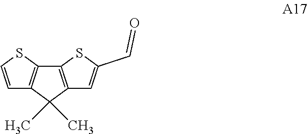

General procedure for A17: Yan et al. (J. Org. Chem., 2008, 73, 17, 6587-6594)

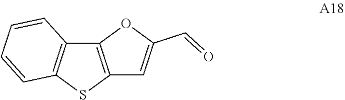 [SMILES: O=Cc1cc2sc3ccccc3c2o1]

General procedure for A18: Svoboda et al. (Collect. Czech. Chem. Commun., 1996, 61, 888-900)

1. A chemical compound of the general formula Ia or Ib 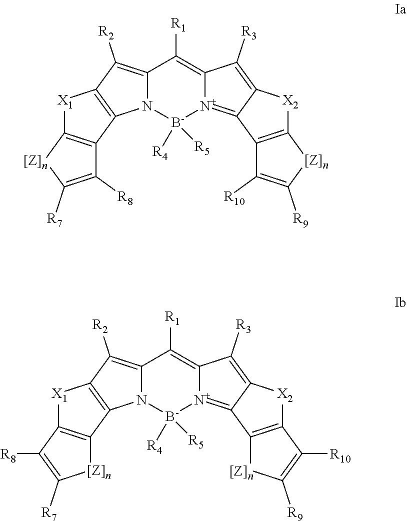
wherein:
X₁ and X₂ are each independently O, S or NR₆, where R₆ is selected from the group consisting of H, alkyl, alkoxy, amino, aryl, and heteroaryl;
R₁ is selected from the group consisting of F, fluorinated or partially fluorinated alkyl, and an aromatic heterocyclic 5-membered ring or 6-membered ring or an aromatic homocyclic 6-membered ring;
R₂ and R₃ are each independently selected from the group consisting of H, halogen, CN, alkyl, alkoxy, amino, aryl, and heteroaryl;
R₄ and R₅ are each independently selected from the group consisting of halogen, preferably F, and fluorinated or partially fluorinated alkyl;
Z is in each case independently selected from the group consisting of O, S, CH₂, CHR₁₁, CR₁₂R₁₃, SiHR₁₁, SiR₁₂R₁₃, NH, NR₁₄, PR₁₅, where R₁₁, R₁₂, R₁₃, R₁₄, and R₁₅ are each independently selected from the group consisting of halogen, alkyl, alkoxy, amino, aryl, and heteroaryl, where n is in each case independently 1 or 2;
R₇ and R₈ and/or R₉ and R₁₀ in each case together form a heterocyclic 5-membered ring or 6-membered ring having at least one heteroatom selected from the group consisting of O, S, N, Si or P, or form a homocyclic 6-membered ring, it being possible for the heterocyclic 5-membered ring or 6-membered ring or homocyclic 6-membered ring to be fused to further rings in each case.

2. The chemical compound as claimed in claim 1, wherein R₁ is selected from the group consisting of F, CF₃, C₂F₅, and an aromatic heterocyclic 5-membered ring or 6-membered ring or an aromatic homocyclic 6-membered ring.

3. The chemical compound as claimed in claim 1, wherein R₇ and R₈ and/or R₉ and R₁₀ in each case together form an aromatic homocyclic 6-membered ring.

4. The chemical compound as claimed in claim 1, wherein R₇ and R₈ and/or R₉ and R₁₀ in each case together form an aromatic heterocyclic 5-membered ring or 6-membered ring having at least one heteroatom selected from the group consisting of O, S, N, Si or P.

5. The chemical compound as claimed in claim 1, wherein R₂ is the same as R₃, R₄ is the same as R₅, and/or R₇ and R₈ are the same as R₉ and R₁₀.

6. The chemical compound as claimed in claim 1, wherein the chemical compound has the general formula IIa, IIb, IIc and/or IId: 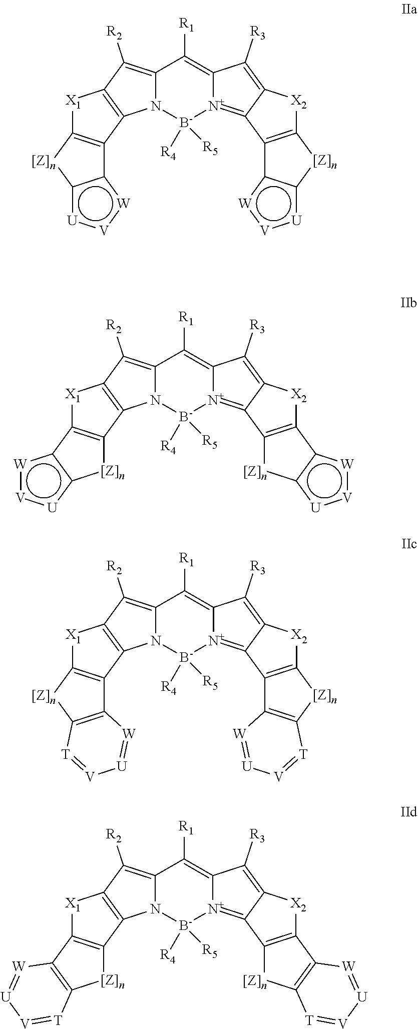
where U, V, and W in formula IIa and IIb are each independently selected from the group consisting of CR₁₆, O, S, N, NR₁₇, where R₁₆ and R₁₇ are each independently selected from the group consisting of H, halogen, alkyl, alkoxy, alkylthiooxy, amino, aryl, and heteroaryl;
where T, U, V, and W in formula IIc and IId are each independently selected from the group consisting of CH, CR₁₈, and N, where R₁₈ is in each case independently selected from the group consisting of halogen, alkyl, alkoxy, alkylthiooxy, amino, aryl, and heteroaryl, wherein U, V, and W in formula IIa and IIb or T, U, V, and W in formula IIc and IId may be fused to a heterocyclic 5-membered ring or 6-membered ring having at least one heteroatom selected from the group consisting of O, S, and N or a homocyclic 6-membered ring;
where Z is in each case independently selected from the group consisting of O, S, CH₂, CHR₁₁, CR₁₂R₁₃, SiHR₁₁, SiR₁₂R₁₃, NH, NR₁₄, PR₁₅, where R₁₁, R₁₂, R₁₃, R₁₄, and R₁₅ are each independently selected from the group consisting of alkyl, alkoxy, amino, aryl, and heteroaryl, and where n is in each case independently 1 or 2.

7. The chemical compound as claimed in claim 6, wherein at least one U, V, and W in formula IIa and IIb is an O or S;
wherein T, U, V, and W in formula IIc and IId are each independently selected from the group consisting of CH and CR₁₈, where R₁₈ is in each case independently selected from the group consisting of alkyl, alkoxy, aryl, and heteroaryl, and/or
wherein at least U or V in formula IIc and IId is CR₁₈, where R₁₈ is selected from the group consisting of alkyl, alkoxy, aryl, and heteroaryl, or T, U, V, and W in formula IIc and IId are each independently CH or CR₁₈, where R₁₈ is alkyl, preferably, T, U, V, and W in formula IIc and IId are H.

8. The chemical compound as claimed in claim 1, wherein Z is in each case independently selected from the group consisting of O, S, CH₂, CHR₁₁, CR₁₂R₁₃, SiHR₁₁, SiR₁₂R₁₃, NR₁₄, PR₁₅, where R₁₁, R₁₂, R₁₃, R₁₄, and R₁₅ are each independently selected from the group consisting of alkyl, alkoxy, or Z is in each case independently selected from the group consisting of O, S, CH₂, CHR₁₁, and CR₁₂R₁₃, where R₁₁, R₁₂, and R₁₃ are each independently selected from the group consisting of alkyl, aryl, and heteroaryl, and/or wherein n is 1.

9. The chemical compound as claimed in claim 1, wherein R₄ and R₅ are F, and/or X₁ and X₂ are each O or S.

10. The chemical compound as claimed in claim 1, wherein R₂ and R₃ are each independently selected from the group consisting of H, alkyl, alkoxy, aryl, and heteroaryl.

11. The chemical compound as claimed in claim 1, wherein Z is selected from CH₂, CHR₁₁, and CR₁₂R₁₃, where R₁₁, R₁₂, and R₁₃ are each independently selected from the group consisting of alkyl, alkoxy, aryl and heteroaryl, and/or wherein n is 1.

12. The chemical compound as claimed in claim 1, wherein the chemical compound is selected from the group consisting of:

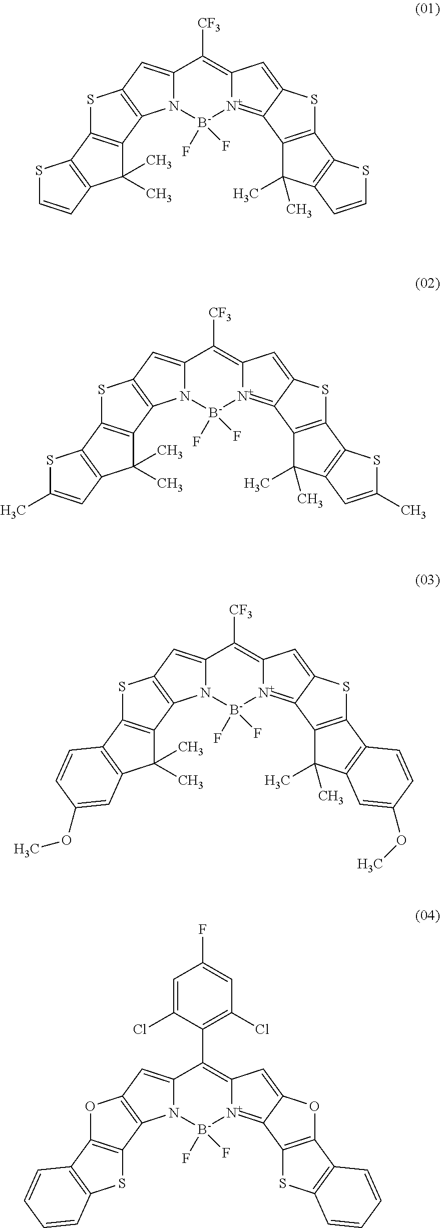

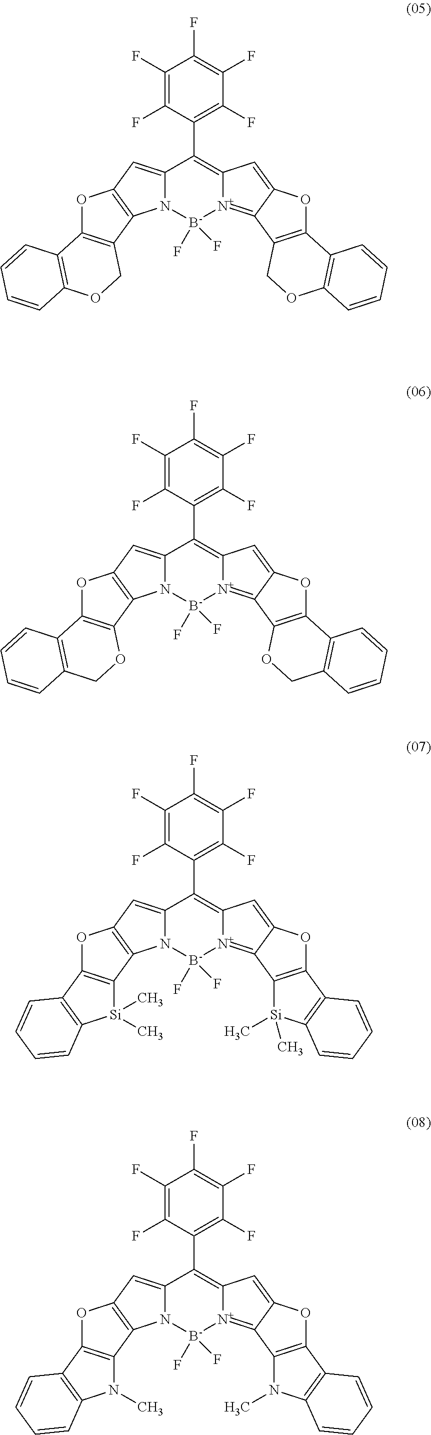 [SMILES: Fc1c(F)c(F)c(C2=C3C=c4oc5c(c4=[N+]3[B-](F)(F)n3c2cc2oc4c(c23)COc2ccccc2-4)COc2ccccc2-5)c(F)c1F ; Fc1c(F)c(F)c(C2=C3C=c4oc5c(c4=[N+]3[B-](F)(F)n3c2cc2oc4c(c23)OCc2ccccc2-4)OCc2ccccc2-5)c(F)c1F ; C[Si]1(C)c2ccccc2-c2oc3c(c21)=[N+]1C(=C(c2c(F)c(F)c(F)c(F)c2F)c2cc4oc5c(c4n2[B-]1(F)F)[Si](C)(C)c1ccccc1-5)C=3 ; Cn1c2ccccc2c2oc3c(c21)=[N+]1C(=C(c2c(F)c(F)c(F)c(F)c2F)c2cc4oc5c6ccccc6n(C)c5c4n2[B-]1(F)F)C=3]

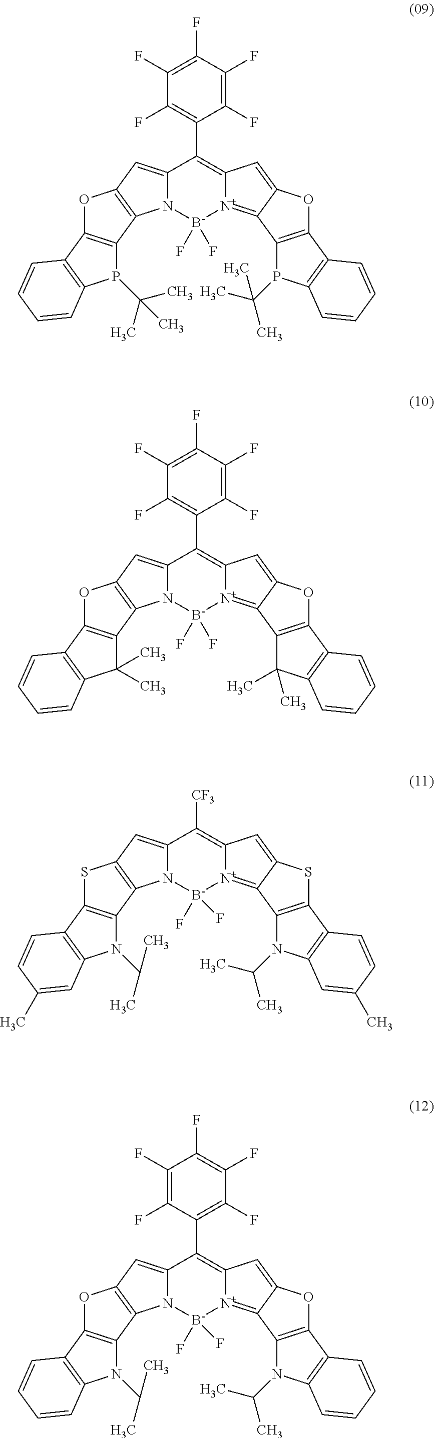 [SMILES: CC(C)(C)p1c2ccccc2c2oc3c(c21)=[N+]1C(=C(c2c(F)c(F)c(F)c(F)c2F)c2cc4oc5c6ccccc6p(C(C)(C)C)c5c4n2[B-]1(F)F)C=3 ; CC1(C)c2ccccc2-c2oc3c(c21)=[N+]1C(=C(c2c(F)c(F)c(F)c(F)c2F)c2cc4oc5c(c4n2[B-]1(F)F)C(C)(C)c1ccccc1-5)C=3 ; Cc1ccc2c3sc4c(c3n(C(C)C)c2c1)=[N+]1C(=C(C(F)(F)F)c2cc3sc5c6ccc(C)cc6n(C(C)C)c5c3n2[B-]1(F)F)C=4 ; CC(C)n1c2ccccc2c2oc3c(c21)=[N+]1C(=C(c2c(F)c(F)c(F)c(F)c2F)c2cc4oc5c6ccccc6n(C(C)C)c5c4n2[B-]1(F)F)C=3]

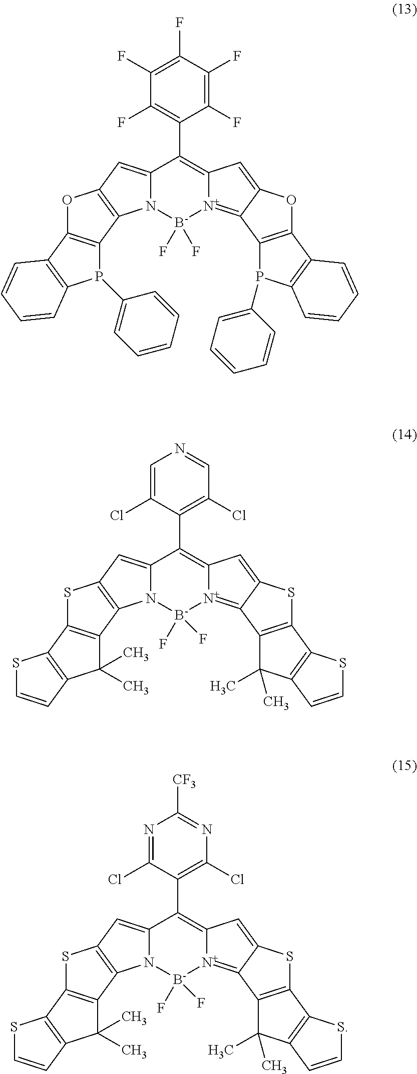 [SMILES: Fc1c(F)c(F)c(C2=C3C=c4oc5c6ccccc6p(-c6ccccc6)c5c4=[N+]3[B-](F)(F)n3c2cc2oc4c5ccccc5p(-c5ccccc5)c4c23)c(F)c1F ; CC1(C)c2ccsc2-c2sc3c(c21)=[N+]1C(=C(c2c(Cl)cncc2Cl)c2cc4sc5c(c4n2[B-]1(F)F)C(C)(C)c1ccsc1-5)C=3 ; CC1(C)c2ccsc2-c2sc3c(c21)=[N+]1C(=C(c2c(Cl)nc(C(F)(F)F)nc2Cl)c2cc4sc5c(c4n2[B-]1(F)F)C(C)(C)c1ccsc1-5)C=3]

13. An optoelectronic component comprising a first electrode, a second electrode, and a layer system, the layer system being arranged between the first electrode and the second electrode, wherein at least one layer of the layer system comprises at least one chemical compound as claimed in claim 1.

14. The optoelectronic component (10) as claimed in claim 13, wherein the optoelectronic component comprises a layer system having at least one photoactive layer, wherein the at least one photoactive layer comprises the at least one chemical compound.

15. (canceled)

16. The chemical compound as claimed in claim 1, wherein R₁ is an aromatic ring selected from a heterocyclic 5-membered ring, a heterocyclic 6-membered ring, or a homocyclic 6-membered ring; wherein at least two hydrogen atoms of the aromatic ring are substituted by F, Cl and/or CF₃.

17. The chemical compound as claimed in claim 3, wherein at least one hydrogen atom of the homocyclic 6-membered ring is substituted by halogen, alkyl, alkoxy, aryl or heteroaryl and/or where the homocyclic 6-membered ring is not fused to further rings.

18. The chemical compound as claimed in claim 4, at least one hydrogen atom of the heterocyclic 5-membered ring or 6-membered ring is substituted by halogen, alkyl, alkoxy, aryl, or heteroaryl and/or where the heterocyclic 5-membered ring or 6-membered ring is not fused to further rings.

19. The chemical compound as claimed in claim 7, wherein U or W is an O or S in formula IIa and IIb.

20. The chemical compound as claimed in claim 7, wherein T, U, V, and W in formula IIc and IId are H.

21. The chemical compound as claimed in claim 10, wherein R₂ and R₃ are H or alkyl, particularly preferably H, methyl, ethyl, or propyl.
